(19) United States
(12) Patent Application Publication
(10) Pub. No.: US 2012/0280235 A1
(43) Pub. Date: Nov. 8, 2012

(54) THIN FILM FET DEVICE AND METHOD FOR FORMING THE SAME

(75) Inventor: Yanzhao LI, Beijing (CN)

(73) Assignee: BOE TECHNOLOGY GROUP CO., LTD., Beijing (CN)

(21) Appl. No.: 13/461,905

(22) Filed: May 2, 2012

(30) Foreign Application Priority Data
May 3, 2011 (CN) 201110113190.4

(51) Int. Cl. H01L 29/786; H01L 51/40

(52) U.S. Cl. 257/57; 438/34; 257/E51.005; 257/E29.273

(57) ABSTRACT

A thin film FET device and a method of forming the same are disclosed. The method comprises: etching a single crystal silicon thin film layer on an insulating thin film layer of an SOI substrate, wherein the etched single crystal silicon thin film layer is used as a channel; forming a gate insulating layer on the SOI substrate that has the single crystal silicon channel formed thereon; and forming a gate electrode, a drain electrode, and a source electrode.

### BACKGROUND

One or more embodiments of the present disclosure relate to a thin film FET device and a method for forming the same.

The conventional thin film field-effect transistor (FET) (i.e., thin film transistor, TFT) switching device, in general, uses an amorphous silicon thin film deposited on a glass substrate as a channel material, or has a channel region formed by crystallizing the amorphous silicon thin film using excimer laser annealing (ELA), metal induced crystallization (MIC), solid phase crystallization (SPC), or other process in subsequent processes.

In the case in which the amorphous silicon thin film is used as the channel material (active layer), the requirements of organic light-emitting display, which is developed rapidly at present, can not be satisfied, since intrinsic carriers of amorphous silicon have a very low mobility that is generally lower than 1 cm²V⁻¹s⁻¹.

Therefore, silicon thin films having relative higher carrier mobility, such as polysilicon, micro crystal silicon, and so on, are also used widely at present to replace the amorphous silicon thin film as the channel material of the TFT device. However, the polysilicon thin film may usually make properties of the TFT devices on a substrate nonuniform because of nonuniform crystallization of the polysilicon thin film. Further, the yield of organic light-emitting diodes manufactured on the basis of the TFT devices may be influenced substantially.

### SUMMARY

One or more embodiments of the disclosure provide a thin film FET device and a method for forming the same.

According to one or more embodiments of the disclosure, a method for forming a thin film FET device is provided, which comprises: etching a single crystal silicon thin film layer on an insulating thin film layer of a silicon-on-insulator (SOI) substrate, the etched single crystal silicon thin film layer being used as a channel; forming a gate insulating layer on the SOI substrate having the single crystal silicon channel formed thereon; and forming a gate electrode, a drain electrode and a source electrode.

According to one or more embodiments of the disclosure, a thin film FET device is provided, which comprises: an SOI substrate comprising a single crystal silicon underlayer, an insulating thin film layer, and a single crystal silicon thin film layer, the single crystal silicon thin film layer being etched to form a channel; a gate insulating layer covering the SOI substrate; and a gate electrode, a drain electrode, and a drain electrode.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a schematic view showing a structure of an SOI substrate according to embodiment 1 of the disclosure;

FIG. 2 is a schematic view showing a structure of the SOI substrate according to embodiment 1 of the disclosure after being photolithographed and etched;

FIG. 3 is a schematic view showing a resultant structure after a gate insulating layer is formed on the SOI substrate according to embodiment 1 of the disclosure;

FIG. 4 is a schematic view of a structure resulting from forming a gate metal layer on the SOI substrate according to embodiment 1 of the disclosure;

FIG. 5 is a schematic view of a structure resulting from forming a metal gate on the SOI substrate according to embodiment 1 of the disclosure via photolithographing and etching;

FIG. 6 is a schematic view of a structure resulting from forming a passivation layer on the SOI substrate according to embodiment 1 of the disclosure;

FIG. 7 is a schematic view of a structure resulting from forming depositing holes through the passivation layer on the SOI substrate according to embodiment 1 of the disclosure via photolithographing and etching;

FIG. 8 is a schematic view showing a structure of the thin film FET device according to embodiment 1 of the disclosure after source and drain electrodes are formed; and

FIG. 9 is a schematic view of a structure of the thin film FET device according to embodiment 2 of the disclosure.

### DETAILED DESCRIPTION

A method of forming a thin film FET device provided by an embodiment of the disclosure, comprises the following steps.

Step S1: photolithographing and etching a single crystal silicon thin film layer on an insulating thin film layer of an SOI substrate, wherein the etched single crystal silicon thin film layer is used as a channel.

Here, the silicon-on-insulator substrate is also named as “SOI” substrate, and is formed by implanting oxygen element into an ordinary silicon wafer of a single crystal silicon to form a deeply buried insulating layer, which works as a separation layer and spaces the single crystal silicon at both sides thereof apart. The SOI substrate from bottom up includes a single crystal silicon underlayer, the insulating thin film layer, and the single crystal silicon thin film layer, the single crystal silicon thin film layer is photolithographed and etched, and the etched single crystal silicon thin film layer is used as a channel of a thin film FET.

In the SOI substrate of an example, the single crystal silicon underlayer has a thickness of 100-500 m, the insulating thin film layer has a thickness of 5 nm-4 m, and the single crystal silicon thin film layer has a thickness of 5-1500 nm.

Step S2: forming a gate insulating layer on the etched SOI substrate.

The gate insulating layer is formed on the SOI substrate that has the single crystal silicon channel formed thereon, and the gate insulating layer may be silicon nitride or silicon oxide and has a thickness of 1-250 nm for example.

Step S3: forming a gate electrode, a source electrode, and a drain electrode.

After the channel and the gate insulating layer are formed, the gate electrode, the source electrode, and the drain electrode are formed. Thereby, the thin film FET device is obtained.

A more detailed process of the method for forming the thin film FET device according to an embodiment of the disclosure is related to the formation of the gate electrode, the source electrode, and the drain electrode is introduced in detail. The method comprises particularly the following steps.

Step S11: photolithographing and etching a single crystal silicon thin film layer on an insulating thin film layer of an SOI substrate, wherein the etched single crystal silicon thin film layer is used as a channel.

References may be made to step S1.

Step S12: forming a gate insulating layer on the etched SOI substrate.

References may be made to step S2.

Step S13: forming on the gate insulating layer a metal gate as a gate electrode, or using a single crystal silicon underlayer contained by the SOI substrate and located under the insulating thin film layer as the gate.

The gate metal of the metal gate electrode may comprise a conductive metal material such as Mo, Al, Cr, or the like, an alloy, or other composite material, and the metal gate formed by sputtering has a thickness of 30-1000 nm for example.

Step S14: covering the gate insulating layer and the metal gate or the gate insulating layer with a passivation layer.

The passivation layer may be an insulating substance such as silicon oxide, silicon nitride, organic material, or the like. Being an example, silicon nitride may be used which is deposited via plasma enhanced chemical vapor deposition (PECVD), and the passivation layer may has a thickness of 30-1500 nm.

Step S15: forming a drain electrode and a source electrode at selected locations of the passivation layer, which penetrate the gate insulating layer and the passivation layer to contact the single crystal silicon thin film layer.

The electrode metal material of the source electrode and the drain electrode may comprise a conductive metal material, such as Mo, Al, Cr, or the like, an alloy, or other composite material, and the source electrode and the drain electrode may have thicknesses of 30-1000 nm for example.

Steps S13-S15 realize the procedure of forming the gate electrode, the source electrode, and the drain electrode described by step S3, and, in addition to the above mentioned ones, any conventional methods or other applicable methods may be used to form the gate electrode, the source electrode and the drain electrode. According to one or more embodiments of the disclosure, the channel, which is formed using the single crystal silicon thin film layer on the insulating thin film layer of the SOI substrate, has a high carrier mobility, and make the overall uniformity of the resultant thin film FET device be improved, so that the yield of the TFT device is enhanced further.

Hereinafter, the detailed forming procedure of forming the metal gate on the gate insulating layer or using the single crystal silicon underlayer included in the SOI substrate and located under the insulating thin film layer as the gate and the thin film FET devices formed by the same will be described respectively by means of particular embodiments.

### Embodiment 1

In the method of forming a thin film FET device according to embodiment 1 of the disclosure, a metal gate electrode is formed on a gate insulating layer for manufacturing the thin film FET device. The process of the method comprises following steps as following.

Step S101: applying a photoresist on a single crystal silicon thin film layer of an SOI substrate, and performing exposure and developing via photolithograph in regions outside or other than those in which a channel is to be formed.

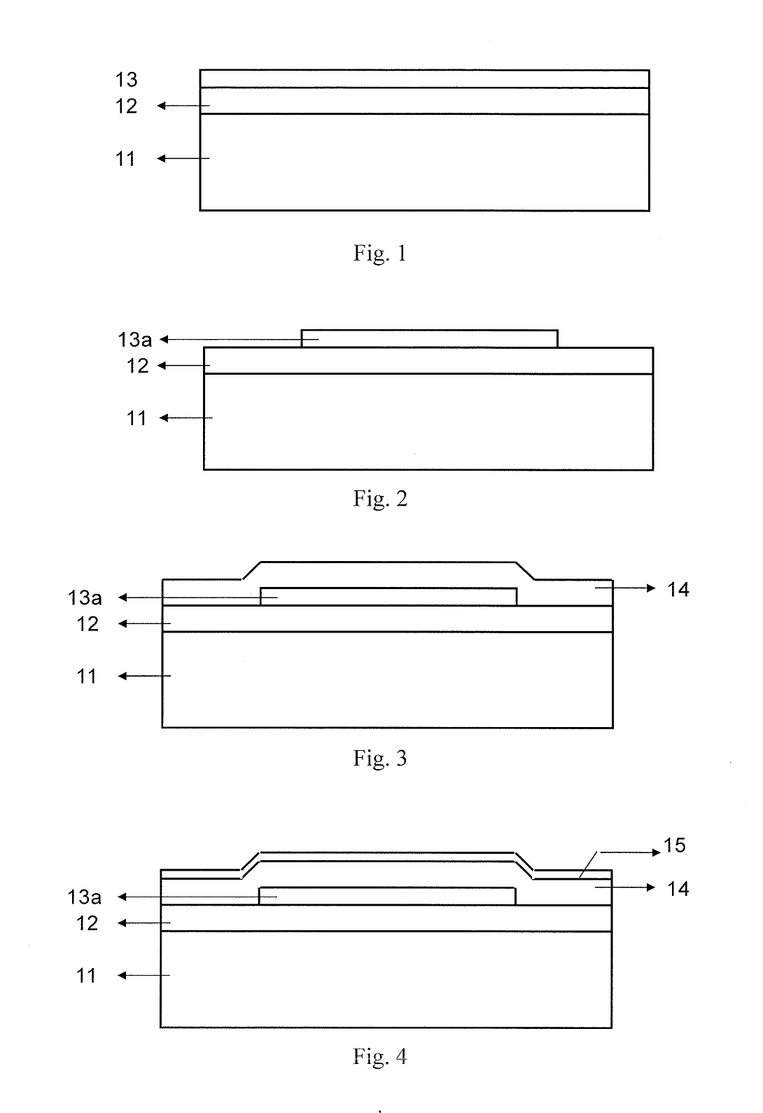

The structure of the SOI substrate is shown in FIG. 1, and comprises from bottom up a single crystal silicon underlayer 11, an insulating thin film layer 12, and the surface single crystal silicon thin film layer 13. The photoresist is applied at a side of the single crystal silicon thin film layer of the SOI substrate by spin coating, AZ series of photoresist may be used, and the photoresist on the single crystal silicon thin film layer which needs to be etched is removed by exposure and developing so as to facilitate the etching performed on the single crystal silicon thin film layer.

The single crystal silicon underlayer may have a thickness of 100-500 m, more preferably, 100-300 m; the insulating thin film layer may have a thickness of 5 nm-4 m, more preferably, 30-50 nm; and the single crystal silicon thin film layer may have a thickness of 5-1500 nm, more preferably, 5-500 nm.

The single crystal silicon underlayer 11 and the single crystal silicon thin film layer 13 included in the SOI substrate both may be n-type silicon material or p-type silicon material, the resistivities of which are typically of 1×10⁻⁴ Ω·cm to 100 Ω·cm. In practical application, the selection of the SOI substrate is not limited to a certain resistivity and a certain conductive type.

According to practical requirements, the n-type silicon material or the p-type silicon material at the surface layer of the single crystal silicon thin film layer may be doped, and thereby be transformed into a p-type silicon material or a n-type silicon material. In particular, doping and activating processes may be performed selectively to fulfill the desired functions of the device. For example, the n-type silicon material in some regions of the surface layer of the single crystal silicon thin film layer may be doped with boron (B) to be transformed into a p-type silicon material, so that the function of complementary metal oxide semiconductor (CMOS) is realized.

Step S102: etching the single crystal silicon thin film layer exposed after exposing and developing, wherein the etched single crystal silicon thin film layer is used as a channel.

As shown in FIG. 2, after the photolithographing and etching are performed on the single crystal silicon thin film layer 13, the etched single crystal silicon thin film layer 13a is obtained, which functions as a channel. As an example, the exposed portions of the single crystal silicon thin film layer may be etched using dry etching.

The above described step S101 and step S102 carry out the photolithographing and etching performed on the single crystal silicon thin film layer on the insulating thin film layer of the SOI substrate, and the etched single crystal silicon thin film layer is used as the channel.

Step S103: forming a gate insulating layer on the SOI substrate that has the single crystal silicon channel formed thereon.

As shown in FIG. 3, the gate insulating layer 14 is formed on the SOI substrate that is subjected to the photolithographing and etching to cover the single crystal silicon thin film layer 13a and the exposed insulating thin film layer 12.

There may be three exemplary following methods to form the gate insulating layer on the SOI substrate.

Method 1: depositing silicon oxide on the etched SOI substrate to form the gate insulating layer.

A PECVD process may be used to deposit the silicon oxide, and the gate insulating layer is formed by depositing the silicon oxide on the etched SOI substrate.

Method 2: thermally oxidizing the etched SOI substrate to form the gate insulating layer.

A dry thermal oxidization process may be performed on the silicon material at the upper surface layer of the etched SOI substrate in an atmosphere of pure oxygen at a temperature of 400-1500° C. for example, and thus the gate insulating layer may be formed by the thermal oxidization.

Method 3: depositing silicon nitride on the etched SOI substrate to form the gate insulating layer.

The silicon nitride may be deposited by using a PECVD process, and the gate insulating layer may be formed by depositing the silicon nitride on the etched SOI substrate.

The gate insulating layers formed by any of the above described methods may have thicknesses of 1-250 nm, and, more preferably, the thicknesses of the gate insulating layers may be of 30-250 nm.

Step S104: sputtering a gate metal material onto the gate insulating layer to from a gate metal layer.

The gate metal material is sputtered in a vacuum with a pressure not higher than 10 Pa to form the gate metal layer. More preferably, a gate metal material of Mo may be sputtered in a vacuum with a pressure of 1×10⁻⁵ Pa. As shown by FIG. 4, the gate metal layer 15 is formed by sputtering the gate metal material.

Step S105: applying a photoresist onto the gate metal layer, and exposing and developing regions outside or other than those in which a metal gate electrode needs to be formed.

By applying the photoresist onto the gate metal layer and then removing by the exposing and developing the photoresist in the regions outside or other than those in which the metal gate electrode needs to be formed, the portions in which the metal gate electrode needs to be formed is covered, so that the portions in which the metal gate does not need to be formed are allowed to be etched. Preferably, the AZ series of photoresist may be selected to perform the spin coating and covering.

Step S106: etching the gate metal layer in the regions exposed after the exposing and developing, in which the etched gate metal layer is used as the metal gate electrode.

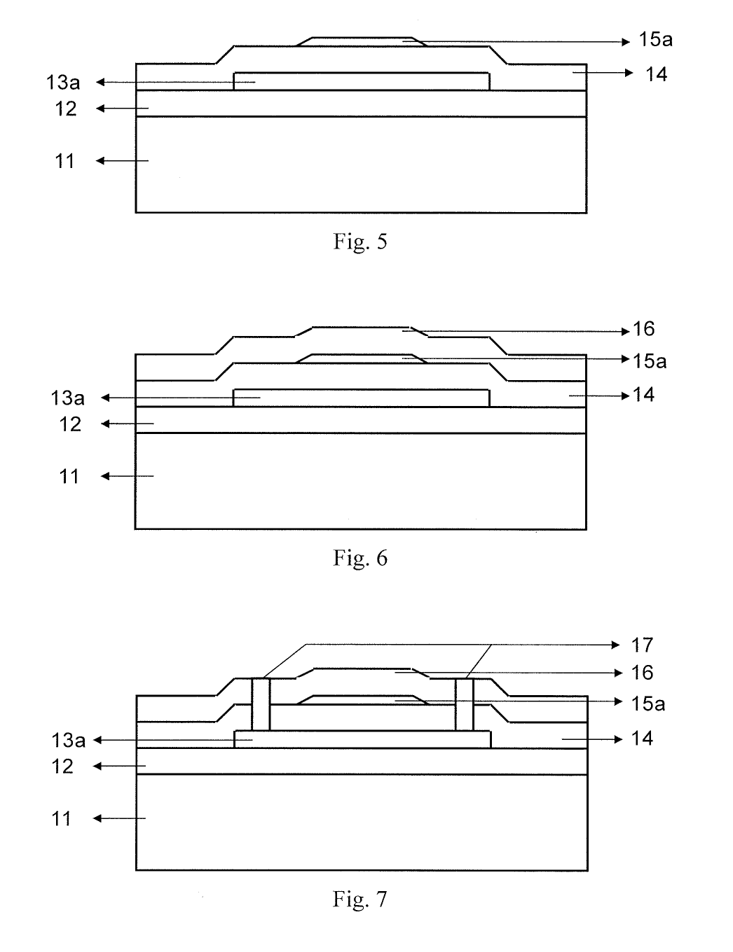

A dry etching may be used to etch the gate metal layer in the exposed regions completely. As shown in FIG. 5, the metal gate electrode 15a is obtained after the gate metal layer 15 is photolithographed and etched.

The above described step S104 to step S106 achieve the metal gate electrode formed on the gate insulating layer.

Step S107: covering the gate insulating layer and the metal gate with a passivation layer.

The passivation layer may be formed by depositing silicon nitride on the gate insulating layer and the metal gate using plasma enhanced chemical vapor deposition (PECVD). As shown in FIG. 6, the gate insulating layer 14 and the metal gate electrode 15a are covered with the passivation layer 16.

Step S108: applying photoresist to the passivation layer, and exposing and developing regions in which source and drain electrodes need to be formed.

Regions in which no source and drain electrodes need to be formed are covered according to predetermined patterns of the source and drain electrodes. Preferably, AZ series of photoresist may be used to perform spin coating and covering. The regions in which no source and drain electrodes need to be formed is covered by applying the photoresist to the passivation layer and then removing by exposure and development the photoresist in regions in which the source and drain electrodes need to be formed.

Step S109: etching the passivation layer exposed after performing the exposure and development to form depositing holes for the source and drain electrodes which penetrate the gate insulating layer and the passivation layer.

The gate insulating layer and the passivation layer may be etched by using dry etching to expose the single crystal silicon thin film layer used as the channel and form the depositing holes. As shown in FIG. 7, two depositing holes 17 for the source and drain electrodes are obtained.

Step S110: depositing electrode metal material in the depositing holes using sputtering to form the source and drain electrodes that contact the single crystal silicon thin film layer.

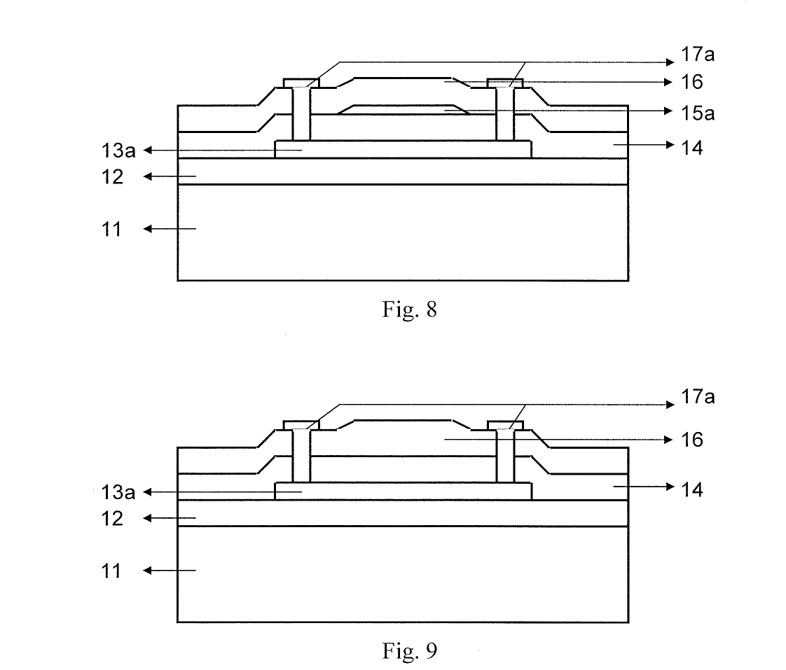

As shown in FIG. 8, after the electrode metal material is deposited in the depositing holes 17, the source and drain electrodes 17a are obtained, wherein, optionally, the source and drain electrodes may be higher than the passivation layer by a predetermined height as shown in FIG. 8.

The above described step S108 to step S110 realize the formation of the drain and source electrodes at selected locations of the passivation layer, which penetrate the gate insulating layer and the passivation layer to contact the single crystal silicon thin film layer.

The structure of the thin film FET device, which is formed using the above described method of forming the thin film FET device according to embodiment 1 of the disclosure, is shown in FIG. 8. The thin film FET device comprises: the SOI substrate, which from bottom up includes the single crystal silicon underlayer 11, the insulating thin film layer 12 and the single crystal silicon thin film layer 13, and in which the single crystal silicon thin film layer forms the channel after being photolithographed and etched; the gate insulating layer 14 covering the SOI substrate; the formed gate electrode 15a, in which the gate electrode is of the metal gate electrode 15a formed on the gate insulating layer 14; the passivation layer 16 covering the gate insulating layer 14 and the metal gate electrode 15a; the source and drain electrodes 17a formed at the selected locations of the passivation layer 16, wherein the source and drain electrodes penetrate the gate insulating layer 14 and the passivation layer 16 to contact the single crystal silicon thin film layer 13.

Preferably, the single crystal silicon underlayer and the single crystal silicon thin film layer included in the SOI substrate both may be n-type silicon material or p-type silicon material. Preferably, the surface layer of the single crystal silicon thin film layer may be of p-type silicon material or n-type silicon material that is formed by doping the n-type silicon material or the p-type silicon material.

Preferably, the above described thin film FET device may further comprise an insulating isolation layer and an electrode of indium tin oxide as anode, in which the insulating isolation layer is formed using a deposition process in pixel regions except for the source electrode on the outer surface of the SOI substrate having the source and drain electrodes formed thereon, and the electrode of indium tin oxide is formed in the pixel regions by a deposition process.

### Embodiment 2

A method of forming a thin film FET device according to embodiment 2 of the disclosure forms the thin film FET device by using a single crystal silicon underlayer under an insulating thin film layer included in an SOI substrate as a gate. The process of the method performs the following steps.

Step S201 to Step S203 which are the same as the steps S101 to S103, respectively, and are not described again.

Step S204: covering the gate insulating layer with a passivation layer.

As shown in FIG. 9, the gate insulating layer 14 is covered with the passivation layer 16.

The single crystal silicon underlayer 11 that is contained in the SOI substrate and is located under the insulating thin film layer 12 is used as the gate electrode of the thin film FET to be formed.

Step S205 to Step S207 which are the same as the steps S108 to S110, respectively, and are not described again.

Optionally, step S203 may be omitted, or step S204 may be omitted. In other words, in this embodiment, the gate insulating layer and the passivation layer may be integrated into one insulating layer.

The structure of the thin film FET device, which is formed using the above described method of forming the thin film FET device according to embodiment 2 of the disclosure, is shown in FIG. 9. This thin film FET device is different from the thin film FET device of embodiment 1 shown in FIG. 8 in that the former does not have a separately formed metal gate electrode, but uses the single crystal silicon underlayer 11 of the SOI substrate under the insulating thin film layer as the gate and covers the gate insulating layer 14 with the passivation layer.

The number of masks used in the manufacturing method may be reduced further when this method is adopted to form the thin film FET device.

Optionally, the above described methods of forming the thin film FET device according to the embodiments of the disclosure further comprise: a step of cleaning the SOI substrate to remove silicon oxide at the surface of the SOI substrate before performing step S11 to photolithograph the single crystal silicon thin film layer on the insulating thin film layer of the SOI substrate, which is before step S101 in embodiment 1 or before step S201 in embodiment 2. The cleaning of the SOI substrate may comprise: performing ultrasonic cleaning using acetone and ethanol; performing ultrasonic cleaning using deionized water after steeping using HF solution to remove silicon oxide and dusts on the surface, in which: the ultrasonic cleaning using acetone and ethanol is performed for 5-60 minutes for example; the concentration of the HF solution for steeping is of 0.01-40%, and the steeping is performed for 30 seconds to 10 minutes for example; and the ultrasonic cleaning using deionized water is performed for 1-60 minutes for example.

Optionally, the above described methods of forming the thin film FET device according to the embodiments of the disclosure further comprise: after forming the source and drain electrodes, depositing the insulating isolation layer in the pixel region except for the source electrode on the ourter surface of the SOI substrate having the source and drain electrodes formed thereon; depositing a conductive thin film material such as indium tin oxide (ITO) or the like in the pixel region to form the electrode of indium tin oxide as an anode, which contacts the source electrode through a contact hole; and further forming an organic light-emitting diode (OLED) device on the electrode of indium tin oxide, whereby an active matrix organic light-emitting diode (AMOLED) panel is formed.

The above described methods of forming the thin film FET device according to the embodiments of the disclosure may be applied to not only the formation of a TFT device having a top gate structure but also the formation of other structures using the SOI substrate. For example, the method may be used to form a TFT device having a bottom gate structure, and to form a TFT-OLED device by further performing processes such as a device transfer process on the basis of forming a TFT device.

The thin film FET device and the method of forming the same according to the embodiments of the disclosure use the single crystal silicon thin film layer on the SOI substrate as a channel, so that the contact between the channel region and the insulating layer is quite good; the thin film FET device is formed by using the single crystal silicon as the channel material and using the improved processes, so that the resultant thin film FET device has a favorable conductivity, and the conductive property of the device is improved substantially; the channel is formed by using the single crystal silicon having a relative higher carrier mobility as the channel material, which improves the uniformity and the carrier mobility of the thin film FET device substantially, makes the uniformity and the carrier mobility not be the main hindrance to the thin film FET device any more, and thereby enhances the yield of the TFT device further. This facilitates the use of GOA (Gate On Array) technique substantially, and also makes it possible to manufacture the integration of electronic devices and light-emitting devices.

By improving a channel material and a process for forming a TFT device, the above described methods according to the embodiments of the disclosure can manufacture a TFT device having relative higher uniformity and caner mobility, and can further package and manufacture a TFT-OLED device having enhanced properties.

The embodiment of the disclosure being thus described, it will be obvious that the same may be varied in many ways. Such variations are not to be regarded as a departure from the spirit and scope of the disclosure, and all such modifications as would be obvious to those skilled in the art are intended to be included within the scope of the following claims.

What is claimed is:

1. A method of forming a thin film field effect transistor (FET) device, comprising:
etching a single crystal silicon thin film layer on an insulating thin film layer of an silicon-on-insulator (SOI) substrate, wherein the etched single crystal silicon thin film layer is used as a channel;
forming a gate insulating layer on the SOI substrate that has the single crystal silicon channel formed thereon; and
forming a gate electrode, a drain electrode, and a source electrode.

2. The method according to claim 1, wherein the step of forming the gate electrode, the drain electrode, and the source electrode comprises:
forming on the gate insulating layer a metal gate electrode, or using a single crystal silicon underlayer contained by the SOI substrate and located under the insulating thin film layer as the gate electrode;
covering the gate insulating layer and the metal gate or the gate insulating layer with a passivation layer;
forming a drain electrode and a source electrode at selected locations of the passivation layer, which penetrate the gate insulating layer and the passivation layer to contact the single crystal silicon thin film layer.

3. The method according to claim 1, wherein the step of etching the single crystal silicon thin film layer on the insulating thin film layer of the SOI substrate, wherein the etched single crystal silicon thin film layer is used as the channel, comprises:
applying photoresist on the single crystal silicon thin film layer of the SOI substrate, performing exposing and developing in regions outside those in which the channel is to be formed, etching the single crystal silicon thin film layer exposed after the exposing and developing, wherein the etched single crystal silicon thin film layer is used as the channel.

4. The method according to claim 3, wherein the single crystal silicon underlayer and the single crystal silicon thin film layer included in the SOI substrate both are a n-type silicon material or a p-type silicon material.

5. The method according to claim 4, further comprising: doping the n-type silicon material or the p-type silicon material at a surface layer of the single crystal silicon thin film layer to transform them into a p-type silicon material or a n-type silicon material.

6. The method according to claim 1, wherein the step of forming the gate insulating layer on the SOI substrate that has the single crystal silicon channel formed thereon comprises:
depositing silicon oxide on the etched SOI substrate to form the gate insulating layer; or thermally oxidizing the etched SOI substrate to form the gate insulating layer, wherein the thermally oxidizing is performed at a temperature of 400-1500° C. in an atmosphere of oxygen; or
depositing silicon nitride on the etched SOI substrate to form the gate insulating layer.

7. The method according to claim 2, wherein the step of forming on the gate insulating layer the metal gate comprises:
sputtering a gate metal onto the gate insulating layer in a vacuum with a pressure not higher than 10 Pa to form a gate metal layer;
applying photoresist onto the gate metal layer, exposing and developing regions outside those in which the metal gate electrode needs to be formed, etching the gate metal layer exposed after the exposing and developing, in which the etched gate metal layer is used as the metal gate electrode.

8. The method according to claim 2, wherein the step of covering the gate insulating layer and the metal gate or the gate insulating layer with the passivation layer comprises:
depositing silicon nitride on the gate insulating layer and the metal gate or on the gate insulating layer using plasma enhanced chemical vapor deposition to form the passivation layer.

9. The method according to claim 2, wherein the step of forming the drain electrode and the source electrode at the selected locations of the passivation layer, which penetrate the gate insulating layer and the passivation layer to contact the single crystal silicon thin film layer, comprises:
applying photoresist to the passivation layer, exposing and developing regions in which the source and drain electrodes need to be formed, etching the passivation layer exposed after the exposing and developing to form depositing holes for the source and drain electrodes which penetrate the gate insulating layer and the passivation layer; and
depositing electrode metal in the depositing holes using sputtering to form the source and drain electrodes that contact the single crystal silicon thin film layer.

10. The method according to claim 9, after forming the source and drain electrodes, further comprising:
depositing an insulating isolation layer as a pixel region in a region except for the source electrode on the ourter surface of the SOI substrate having the source and drain electrodes formed thereon; and
depositing an electrode of indium tin oxide as an anode in the pixel region, which contacts the source electrode through a contact hole, and forming an organic light-emitting diode OLED device.

11. A thin film thin film transistor (FET) device comprising:
an silicon-on-insulator (SOI) substrate including a single crystal silicon underlayer, an insulating thin film layer, and a single crystal silicon thin film layer, wherein after being etched, the single crystal silicon thin film layer forms a channel;
a gate insulating layer covering the SOI substrate; and
a gate electrode, a source, and a drain electrode.

12. The thin film FET device according to claim 11, wherein the gate is a metal gate formed on the gate insulating layer, or the single crystal silicon underlayer included in the SOI substrate is used as the gate electrode;
the source electrode and the drain electrode are located at selected locations of a passivation layer, penetrate the gate insulating layer and the passivation layer, and contact the single crystal silicon thin film layer, the passivation layer covering the gate insulating layer and the metal gate or the gate insulating layer.

13. The thin film FET device according to claim 11, wherein the single crystal silicon underlayer has a thickness of 100-500 μm, the insulating thin film layer has a thickness of 5 nm-4 μm, and the single crystal silicon thin film layer has a thickness of 5-1500 nm.

14. The thin film FET device according to claim 13, wherein the the single crystal silicon underlayer and the single crystal silicon thin film layer included in the SOI substrate both are a n-type or p-type silicon material.

15. The thin film FET device according to claim 14, wherein a surface layer of the single crystal silicon thin film layer is a p-type silicon material or a n-type silicon material, which is formed by doping the n-type silicon material or the p-type silicon material.

16. The thin film FET device according to claim 11, wherein the thickness of the gate insulating layer is of 1-250 nm.

17. The thin film FET device according to claim 12, wherein a gate metal of the metal gate comprises Mo, Al, or Cr, and the metal gate has a thickness of 30-1000 nm.

18. The thin film FET device according to claim 12, wherein the passivation layer has a thickness of 30-1500 nm.

19. The thin film FET device according to claim 12, wherein electrode metal material of the source electrode and the drain electrode comprises Mo, Al, or Cr, and the source electrode and the drain electrode have thicknesses of 30-1000 nm.

20. The thin film FET device according to claim 12, further comprising:
an insulating isolation layer, which is formed using deposition process in a region except for the source electrode on the outer surface of the SOI substrate having the source and drain electrodes formed thereon; and
an electrode of indium tin oxide as anode, which is formed in a region except for the source electrode by deposition process, and contacts the source region via a contact hole.
